(19) United States
(12) Patent Application Publication
(10) Pub. No.: US 2025/0063796 A1
(43) Pub. Date: Feb. 20, 2025

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventors: Hiroki NEMOTO, Fuchu Tokyo (JP); Tsuyoshi KACHI, Kanazawa Ishikawa (JP); Hiroaki KATOU, Nonoichi Ishikawa (JP); Kazuyuki SATO, Nonoichi Ishikawa (JP); Toshifumi NISHIGUCHI, Hakusan Ishikawa (JP)

(21) Appl. No.: 18/434,084

(22) Filed: Feb. 6, 2024

Related U.S. Application Data
(63) Continuation of application No. PCT/CN2023/113188, filed on Aug. 15, 2023.

(30) Foreign Application Priority Data
Sep. 19, 2023 (JP) 2023-151705

(51) Int. Cl. H01L 29/417; H01L 21/04; H01L 29/08; H01L 29/16; H01L 29/45; H01L 29/66; H01L 29/78

(52) U.S. Cl. CPC H01L 29/41741; H01L 21/047; H01L 21/0485; H01L 29/0856; H01L 29/1608; H01L 29/45; H01L 29/66068; H01L 29/7813

(57) ABSTRACT

A semiconductor device according to an embodiment includes: a first electrode; a first semiconductor region of a first conductive type provided on the first electrode; a second semiconductor region of a second conductive type provided on the first semiconductor region; a third semiconductor region of a first conductive type provided on the second semiconductor region; a gate electrode provided in the second semiconductor region via a gate insulating film; a contact portion having a first portion and a second portion; and a second electrode electrically connected to the contact portion. The first portion is aligned with the third semiconductor region and a part of the second semiconductor region, and the second portion is provided at a lower end of the first portion and has a width larger than a width of the first portion at an upper end of the third semiconductor region.

### CROSS-REFERENCE TO RELATED APPLICATIONS

This application is based upon and claims the benefit of priority from the prior Japanese Patent Application No. 2023-151705, filed on Sep. 19, 2023; the entire contents of which are incorporated herein by reference.

### FIELD

Embodiments described herein relate generally to a semiconductor device and a method for manufacturing the same.

### BACKGROUND

In a circuit including a metal-oxide-semiconductor field-effect transistor (MOSFET), a surge voltage is superimposed on a drain-source voltage when the MOSFET is turned off due to a floating inductance in the circuit. As a result, the drain-source voltage may exceed the maximum rating of a semiconductor element and break down. However, the MOSFET has a characteristic called avalanche withstand, and under conditions such as a certain energy or less, element breakdown does not occur even if the drain-source voltage exceeds the rated voltage. For this reason, it is important to ensure sufficient avalanche withstand in order to improve the reliability of the MOSFET.

In order to improve the avalanche withstand, it is conceivable to increase the width of the trench contact. However, since the alignment margin of the trench contact is reduced, there is a possibility that the formation position of the trench contact is shifted. In this case, problems arise in that insulation between a gate electrode and a source electrode cannot be sufficiently ensured, or a threshold voltage of the MOSFET fluctuates.

### BRIEF DESCRIPTION OF THE DRAWINGS

FIG. 1 is a sectional view of a semiconductor device according to an embodiment;

FIG. 2 is a view obtained by enlarging a contact portion of FIG. 1;

FIG. 3 is a diagram for describing a shape of a leading end portion of the contact portion according to the embodiment;

FIG. 4 is a flowchart illustrating a first example of a method for manufacturing a semiconductor device according to an embodiment;

FIG. 5A is a process sectional view for describing the first example of the method for manufacturing a semiconductor device according to the embodiment;

FIG. 5B is a process sectional view for describing the first example of the method for manufacturing a semiconductor device according to the embodiment, which is subsequent to FIG. 5A;

FIG. 5C is a process sectional view for describing the first example of the method for manufacturing a semiconductor device according to the embodiment, which is subsequent to FIG. 5B;

FIG. 5D is a process sectional view for describing the first example of the method for manufacturing a semiconductor device according to the embodiment, which is subsequent to FIG. 5C;

FIG. 5E is a process sectional view for describing the first example of the method for manufacturing a semiconductor device according to the embodiment, which is subsequent to FIG. 5D;

FIG. 6 is a flowchart illustrating a second example of the method for manufacturing a semiconductor device according to the embodiment;

FIG. 7A is a process sectional view for describing the second example of the method for manufacturing a semiconductor device according to the embodiment;

FIG. 7B is a process sectional view for describing the second example of the method for manufacturing a semiconductor device according to the embodiment, which is subsequent to FIG. 7A;

FIG. 7C is a process sectional view for describing the second example of the method for manufacturing a semiconductor device according to the embodiment, which is subsequent to FIG. 7B; and

FIG. 7D is a process sectional view for describing the second example of the method for manufacturing a semiconductor device according to the embodiment, which is subsequent to FIG. 7C.

### DETAILED DESCRIPTION

A semiconductor device according to an embodiment includes: a first electrode; a first semiconductor region of a first conductive type provided on the first electrode; a second semiconductor region of a second conductive type provided on the first semiconductor region; a third semiconductor region of a first conductive type provided on the second semiconductor region; a gate electrode provided in the second semiconductor region via a gate insulating film; a contact portion having a first portion and a second portion; and a second electrode electrically connected to the contact portion. The first portion is aligned with the third semiconductor region and a part of the second semiconductor region, and the second portion is provided at a lower end of the first portion and has a width larger than a width of the first portion at an upper end of the third semiconductor region.

Hereinafter, a semiconductor device and a method for manufacturing the same according to embodiments will be described with reference to the drawings. The embodiments do not limit the present invention. The drawings are schematic or conceptual, and the ratio of each portion and the like are not necessarily the same as actual ones. In the specification and the drawings, elements similar to those already described are denoted by the same reference numerals, and detailed description thereof is omitted as appropriate.

In the following description, notations of n⁺, n, n⁻, p⁺, p, and p⁻ may be used to indicate the relative levels of impurity concentrations in the semiconductor region. n⁺ indicates an n-type impurity concentration relatively higher than that of n, and n⁻ indicates an n-type impurity concentration relatively lower than that of n. p⁺ indicates a p-type impurity concentration relatively higher than that of p, and p⁻ indicates a p-type impurity concentration relatively lower than that of p. An n-type, an n⁺-type, and an n⁻-type are examples of the first conductive type in the claims. A p-type, a p⁺-type, and a p⁻-type are examples of the second conductive type in the claims. In the following description, the n-type and the p-type may be reversed. That is, the first conductive type may be a p-type, and the second conductive type may be an n-type.

In the description of the embodiments, a direction from a drain electrode toward a source electrode is referred to as “upper”, and an opposite direction is referred to as “lower”. These directions are based on the relative positional relationship between the drain electrode and the source electrode, and are independent of the direction of gravity.

The impurity concentration of the semiconductor region can be measured by, for example, secondary ion mass spectrometry (SIMS). The relative level of impurity concentration can also be determined from the level of the carrier concentration obtained by, for example, scanning capacitance microscopy (SCM).

The dimension such as a width of a contact portion can be measured by, for example, a transmission electron microscope (TEM), energy dispersive X-ray spectroscopy (EDX), or the like.

### (Semiconductor Device)

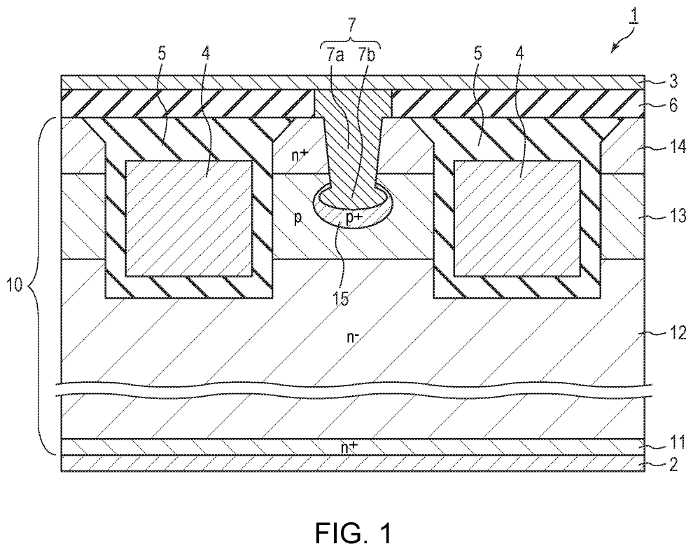

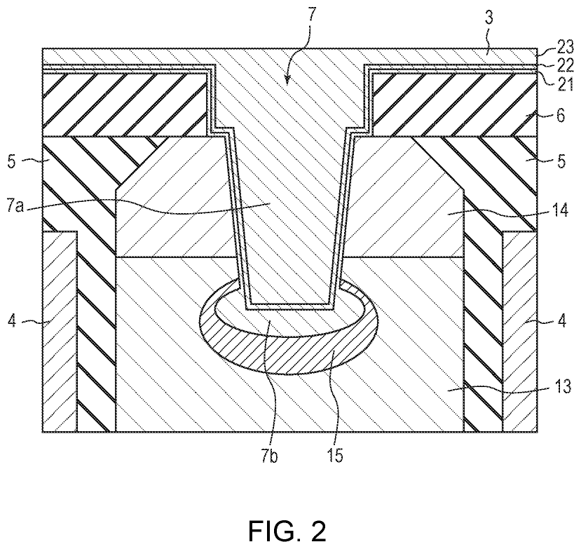

A semiconductor device 1 according to an embodiment will be described with reference to FIGS. 1 to 3. The semiconductor device 1 is configured as a vertical MOSFET.

The semiconductor device 1 includes a drain electrode 2, a source electrode 3, and a semiconductor layer 10 disposed between the drain electrode 2 and the source electrode 3.

The drain electrode 2 functions as a drain electrode of the MOSFET. The source electrode 3 functions as a source electrode of the MOSFET. The drain electrode 2 is disposed to be in contact with a lower surface of the semiconductor layer 10, and the source electrode 3 is disposed on the semiconductor layer 10 via an interlayer insulating film 6.

The drain electrode 2 and the source electrode 3 contain a metal such as tungsten, aluminum, or titanium. The drain electrode 2 is an example of the first electrode in the claims, and the source electrode 3 is an example of the second electrode in the claims.

In the present embodiment, the source electrode 3 has a metal film 21 provided on the interlayer insulating film 6, a metal film 22 provided on the metal film 21, and a metal film 23 provided on the metal film 22. The metal film 21 is made of silicide such as titanium silicide, the metal film 22 is made of titanium nitride or the like, and the metal film 23 is made of tungsten or the like. In the present embodiment, the metal film 21 is also provided to be in contact with a source region 14 and a base region 13.

The semiconductor layer 10 is provided with a drain region 11, a drift region 12, a base region 13, and a source region 14.

The semiconductor layer 10 may be an epitaxial layer, a semiconductor substrate, or a semiconductor substrate and an epitaxial layer disposed on the semiconductor substrate. In the present embodiment, the semiconductor layer 10 is silicon (Si). In this case, arsenic (As), phosphorus (P), antimony (Sb), or the like is used as the n-type impurity. Boron (B) or the like is used as the p-type impurity. The semiconductor layer 10 may be a silicon-based compound semiconductor such as silicon carbide (SIC).

The drain region 11 is a semiconductor region functioning as a drain of the MOSFET. The drain region 11 is provided on the drain electrode 2 and is electrically connected to the drain electrode 2. The drain region 11 is, for example, an n⁺-type semiconductor region, and the n-type impurity concentration thereof is, for example, 1×10¹⁸ cm⁻³ or more and 1×10²¹ cm⁻³ or less. The drain region 11 is an example of the first semiconductor region in the claims.

The drift region 12 is a semiconductor region functioning as a drift region of the MOSFET. The drift region 12 is provided on the drain region 11. The drift region 12 is, for example, an n⁻-type semiconductor region, and the n-type impurity concentration thereof is, for example, 1×10¹⁵ cm⁻³ or more and 2×10¹⁶ cm⁻³ or less. The drift region 12 is an example of the first semiconductor region in the claims. The first semiconductor region may include at least one of the drain region 11 and the drift region 12.

The base region 13 is a semiconductor region functioning as a base region of the MOSFET. The base region 13 is provided on the drift region 12. The base region 13 is adjacent to the gate electrode 4 via a gate insulating film 5. The base region 13 is, for example, a p-type semiconductor region, and the p-type impurity concentration thereof is, for example, 1×10¹⁶ cm⁻³ or more and 1×10²⁰ cm⁻³ or less. The base region 13 is an example of the second semiconductor region in the claims.

When a voltage is applied to the gate electrode 4, a channel is formed in the base region 13, and carriers (electrons in the present embodiment) flow between the drain region 11 and the source region 14. The region (channel region) where the channel is formed is in the vicinity of an interface of the base region 13 with the gate insulating film 5 in the base region 13.

The source region 14 is a semiconductor region functioning as a source region of the MOSFET. The source region 14 is provided on the base region 13. The source region 14 is electrically connected to the source electrode 3 via a contact portion 7. The source region 14 is, for example, an n⁺-type semiconductor region, and the n-type impurity concentration thereof is, for example, 1×10¹⁸ cm⁻³ or more and 1×10²¹ cm⁻³ or less. The source region 14 is an example of the third semiconductor region in the claims.

A high-concentration region 15 is a semiconductor region of a second conductive type provided in the base region 13. The high-concentration region 15 is provided to surround a lower end (leading end portion 7b) of the contact portion 7. The high-concentration region 15 is a region having an impurity concentration of a second conductive type higher than that of the base region 13, and is, for example, a p⁺-type semiconductor region. The p-type impurity concentration of the high-concentration region 15 is, for example, 1×10¹⁸ cm⁻³ or more and 1×10²¹ cm⁻³ or less. The high-concentration region 15 is an example of the fourth semiconductor region in the claims.

The gate insulating film 5 is an insulating film provided to penetrate the base region 13 from the source region 14 to the drift region 12. The gate electrode 4 is provided inside the gate insulating film 5. This gate insulating film 5 is an insulating film penetrating the source region 14 and the base region 13 and embedded in a gate trench provided halfway through the drift region 12. The gate insulating film 5 is made of, for example, an insulating material such as silicon oxide or silicon nitride.

The gate electrode 4 functions as a gate electrode of the MOSFET. The gate electrode 4 is provided in the base region 13 via the gate insulating film 5. In the present embodiment, as illustrated in FIG. 1, the gate electrode 4 is provided from the source region 14 to the drift region 12. The gate electrode 4 extends in a direction perpendicular to the paper surface of FIG. 1. The gate electrode 4 is made of, for example, conductive polysilicon.

A field plate electrode (not illustrated) provided in the gate insulating film 5 and located below the gate electrode 4 may be provided. The field plate electrode is electrically connected to the source electrode 3.

The interlayer insulating film 6 is provided between the source region 14 and the source electrode 3. The interlayer insulating film 6 is made of, for example, an insulating material such as silicon oxide or silicon nitride.

The contact portion 7 is electrically connected to the source electrode 3 and is provided to penetrate the interlayer insulating film 6 and the source region 14 and reach the base region 13. In the present embodiment, the contact portion 7 extends in the direction perpendicular to the paper surface of FIG. 1.

Specifically, the contact portion 7 has a conductive penetration portion 7a connected to the source electrode 3 at an upper end and a conductive leading end portion 7b provided at a lower end of the penetration portion 7a. The penetration portion 7a is provided to penetrate the interlayer insulating film 6 and the source region 14 and reach the base region 13. The leading end portion 7b is provided at the lower end (leading end) of the penetration portion 7a located in the base region 13. The penetration portion 7a is an example of the first portion in the claims, and the leading end portion 7b is an example of the second portion in the claims. In the present embodiment, the leading end portion 7b is integrally formed with the metal film 21.

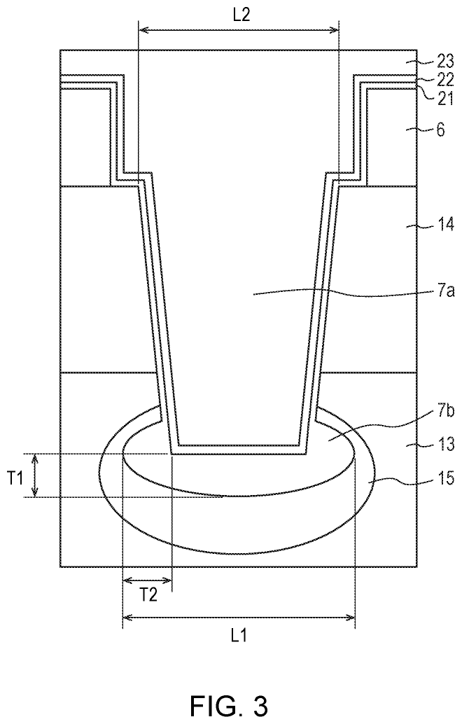

The leading end portion 7b has a shape bulging toward the gate electrode 4. Specifically, the leading end portion 7b has a width larger than a width of the penetration portion 7a at an upper end of the source region 14 (opening width of the source region 14). That is, as illustrated in FIG. 3, a width L1 of the leading end portion 7b is larger than a width L2 of the penetration portion 7a at the upper end of the source region 14.

The width L1 of the leading end portion 7b may be larger than the width of the penetration portion 7a at an upper end of the interlayer insulating film 6 (opening width of the interlayer insulating film 6). More generally, the width of the leading end portion 7b may be larger than the width of the largest portion of the penetration portion 7a.

As illustrated in FIG. 3, a thickness T2 of the leading end portion 7b in a lateral direction (second direction) may be larger than a thickness T1 in a longitudinal direction (first direction). The first direction is a direction from the drain electrode 2 toward the source electrode 3, and the second direction is a direction orthogonal to the first direction. For example, the thickness T2 is defined by a length between the metal film 22 (barrier metal) and the end portion (left end or right) of the leading end portion 7b in the second direction. The thickness T1 is defined by a length between the metal film 22 and the end portion (lower end) of the leading end portion 7b in the first direction.

The leading end portion 7b contains metal silicide. For example, at least a portion (bulging portion) of the leading end portion 7b facing the gate electrode 4 contains metal silicide. The leading end portion 7b is not limited to metal silicide, and may contain a metal material such as titanium (Ti).

The leading end portion 7b contains titanium silicide (TiSi). The leading end portion 7b may contain silicide of a metal other than titanium. For example, the leading end portion 7b may contain silicide of chromium (Cr), zirconium (Zr), molybdenum (Mo), tungsten (W), or hafnium (Hf) (that is, such as chromium silicide, zirconium silicide, molybdenum silicide, tungsten silicide, or hafnium silicide).

As described above, in the semiconductor device 1 of the present embodiment, since the contact portion 7 has the leading end portion 7b bulging toward the gate electrode 4, the distance between the bottom portion of the contact portion 7 and the channel region can be shortened. As a result, minority carriers (holes in the present embodiment) can be efficiently extracted from the leading end portion 7b when the MOSFET is turned off, so that the avalanche withstand of the MOSFET can be improved.

According to the present embodiment, the distance between the bottom portion of the contact portion 7 and the channel region can be shortened without increasing the width of the contact portion 7 (penetration portion 7a). Therefore, since the alignment margin when the contact portion 7 is formed can be ensured, it is possible to sufficiently ensure the insulation between the gate electrode 4 and the source electrode 3 and to suppress the fluctuation of the threshold voltage of the MOSFET.

Therefore, according to the present embodiment, it is possible to provide a semiconductor device capable of improving avalanche withstand without affecting element characteristics.

In the above description, the semiconductor device 1 is a vertical MOSFET, but the semiconductor device 1 may be another semiconductor device having a trench gate structure. For example, when the semiconductor device 1 is an insulated gate bipolar transistor (IGBT), the drain region 11 may be changed to a p⁺-type collector region, or a p⁺-type collector region may be additionally disposed between the drain region 11 and the drain electrode 2. The other points are similar to those of the vertical MOSFET described in the present embodiment. In this case, the source region 14 is an emitter region.

### <Method for Manufacturing Semiconductor Device>

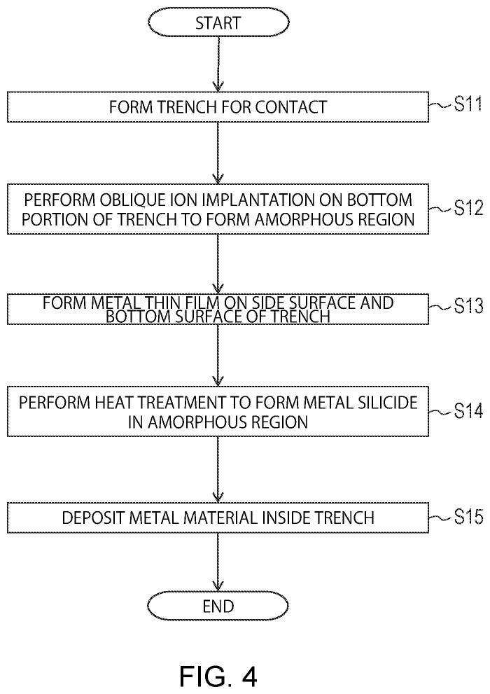

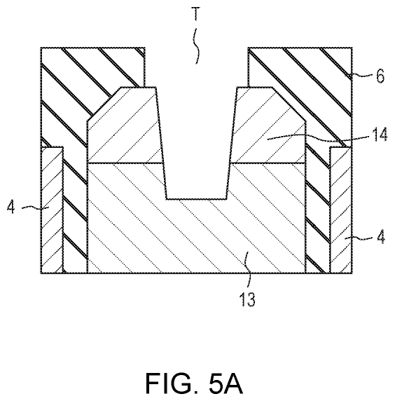

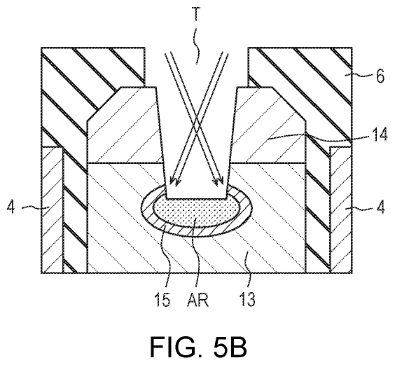

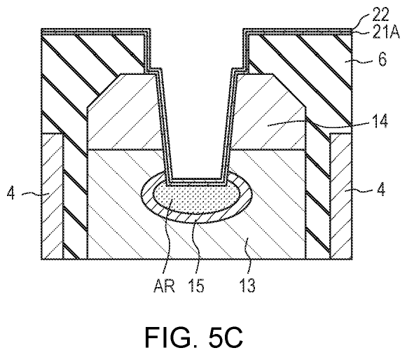

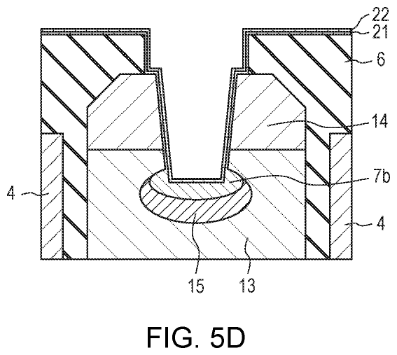

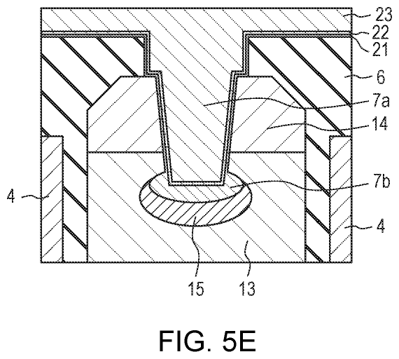

A first example according to a method for manufacturing the semiconductor device 1 will be described with reference to the flowchart of FIG. 4 and the process sectional views of FIGS. 5A to 5E.

Step S11: As illustrated in FIG. 5A, the semiconductor layer 10 in which the gate electrode 4, the base region 13, and the source region 14 are formed and the upper surface is covered with the interlayer insulating film 6 is prepared, and a trench T for contact is formed by reactive ion etching (RIE) or the like. The trench T is formed to penetrate the interlayer insulating film 6 and the source region 14 and reach the base region 13. This step may be performed by two-stage etching. That is, the interlayer insulating film 6 made of silicon oxide or the like is removed, and then the source region 14 and the base region 13 made of silicon or the like are removed.

Step S12: As illustrated in FIG. 5B, oblique ion implantation is performed on the bottom portion of the trench T to form an amorphous region AR. In the present embodiment, the p-type impurity (such as boron, boron fluoride, or aluminum) is ion-implanted in an oblique direction with respect to the bottom surface of the trench T to form the amorphous region AR extending in a lateral direction from the bottom portion of the trench T. In this step, impurity ions are implanted into the bottom portion of the trench T with a speed component in the lateral direction (horizontal surface) as much as possible, thereby forming the amorphous region AR bulging toward the gate electrode 4. Although the high-concentration region 15 is illustrated in FIG. 5B, strictly speaking, the ions implanted in this step are activated by a heat treatment in Step S14 to become the high-concentration region 15.

Step S13: As illustrated in FIG. 5C, a metal thin film is formed on the side surface and the bottom surface of the trench T by sputtering or the like. In the present embodiment, a metal film 21A made of titanium (Ti) is formed on the side surface and the bottom surface of the trench T, and then the metal film 22 made of titanium nitride (TiN) is formed on the metal film 21A. The metal films 21A and 22 are also formed on the interlayer insulating film 6. The formation of titanium nitride may be omitted.

Step S14: As illustrated in FIG. 5D, the heat treatment (annealing) is performed to form metal silicide in the amorphous region AR. The heat treatment is performed, for example, at a temperature around 600° C. for about 30 seconds. By this heat treatment, the metal film 21A is silicided, and the metal film 21 made of titanium silicide is formed. As titanium silicidation of silicon proceeds along the amorphous region AR, the leading end portion 7b having a shape corresponding to the amorphous region AR is formed.

Step S15: As illustrated in FIG. 5E, a metal material such as tungsten (W) is deposited inside the trench T by sputtering or the like. The metal material is also deposited on the metal film 22 on the interlayer insulating film 6, and the metal film 23 constituting the source electrode 3 is formed. The metal material in this step is not limited to tungsten, and may be, for example, aluminum or titanium.

Through the above steps, the semiconductor device 1 according to the embodiment can be manufactured.

The above steps are merely examples. For example, the heat treatment may be performed between Step S12 and Step S13 to electrically activate the impurity ion-implanted in Step S12. The heat treatment of Step S14 may be performed after Step S15.

In the above step, the amorphous region AR is formed by ion implantation of the p-type impurity for forming the high-concentration region 15, but the width of the amorphous region AR may be increased by implanting an inert element such as argon before or after Step S12. Instead of Step S12, the amorphous region AR may be formed by implanting an inert element.

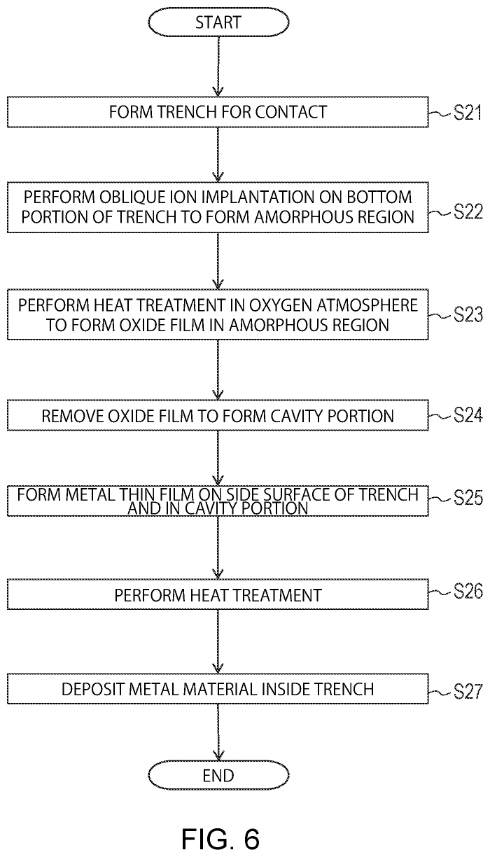

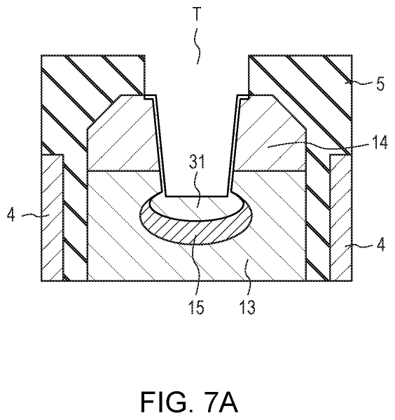

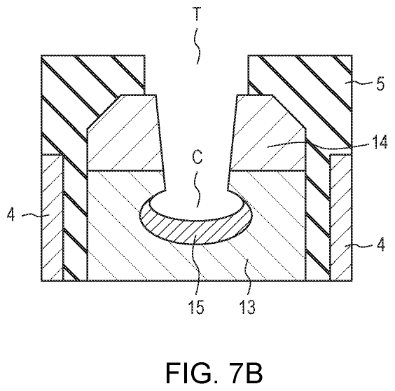

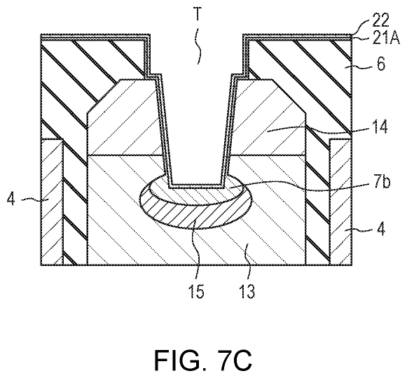

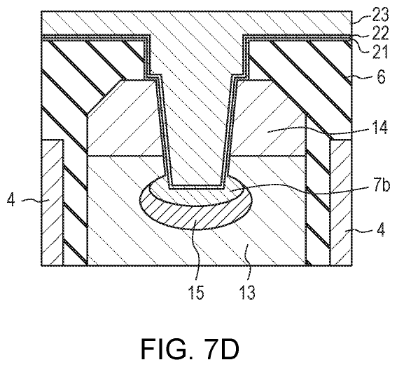

A second example according to the method for manufacturing the semiconductor device 1 will be described with reference to the flowchart of FIG. 6 and the process sectional views of FIGS. 7A to 7D.

Step S21: The semiconductor layer 10 is prepared, and the trench T for contact is formed on the upper surface thereof by RIE or the like. Since this step is similar to Step S11 described above, a detailed description thereof will be omitted.

Step S22: Oblique ion implantation is performed on the bottom portion of the trench T to form an amorphous region AR. Since this step is similar to Step S12 described above, a detailed description thereof will be omitted.

Step S23: As illustrated in FIG. 7A, the heat treatment is performed in an oxygen atmosphere to form an oxide film 31 in the amorphous region AR. Since the amorphous semiconductor layer is easily oxidized, an oxide film is formed along the amorphous region AR in this step. The oxygen atmosphere is, for example, a mixed gas of nitrogen and oxygen, and the proportion of oxygen is 10% or more. The upper limit of the oxygen proportion is not particularly limited, but is, for example, about 50%.

Step S24: As illustrated in FIG. 7B, selective etching such as wet etching is performed to remove the oxide film 31, thereby forming a cavity portion C.

Step S25: As illustrated in FIG. 7C, a metal thin film is formed on the side surface of the trench T and inside the cavity portion C by sputtering or the like. In the present embodiment, the metal film 21A made of titanium (Ti) is formed on the side surface of the trench T and in the cavity portion C. Titanium is deposited in the cavity portion C to form the leading end portion 7b. Thereafter, the metal film 22 made of titanium nitride (TiN) is formed on the metal film 21A. The metal films 21A and 22 are also formed on the interlayer insulating film 6. The formation of titanium nitride may be omitted.

Step S26: The heat treatment (annealing) is performed. As a result, as illustrated in FIG. 7D, the metal film 21A is silicided to become the metal film 21 made of titanium silicide. As for titanium deposited in the cavity portion C, titanium in the peripheral portion in contact with the semiconductor layer 10 becomes titanium silicide, but titanium inside the cavity portion C does not change.

Step S27: As illustrated in FIG. 7D, a metal material is deposited inside the trench T by sputtering or the like. In the present embodiment, tungsten (W) is deposited inside the trench T. The metal material in this step is not limited to tungsten, and may be, for example, aluminum or titanium.

Through the above steps, the semiconductor device 1 according to the embodiment can be manufactured. The metal film 21A to be formed in Step S25 may be a metal film of a metal other than titanium, for example, chromium (Cr), zirconium (Zr), molybdenum (Mo), tungsten (W), or hafnium (Hf). In this case, each of the metal films 21 to be formed in Step S26 is chromium silicide, zirconium silicide, molybdenum silicide, tungsten silicide, or hafnium silicide.

The above steps are merely examples. For example, in Step S22, the amorphous region AR may be formed by ion-implanting an inert element such as argon instead of the p-type impurity.

While certain embodiments described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a first semiconductor region of a first conductive type provided on the first electrode;
a second semiconductor region of a second conductive type provided on the first semiconductor region;
a third semiconductor region of a first conductive type provided on the second semiconductor region;
a gate electrode provided in the second semiconductor region via a gate insulating film;
a contact portion having a first portion aligned with the third semiconductor region and a part of the second semiconductor region, and a second portion provided at a lower end of the first portion and having a width larger than a width of the first portion at an upper end of the third semiconductor region; and
a second electrode electrically connected to the contact portion.

2. The semiconductor device according to claim 1, wherein a thickness of the second portion in a second direction orthogonal to a first direction from the first electrode toward the second electrode is larger than a thickness of the second portion in the first direction.

3. The semiconductor device according to claim 2, wherein the second portion of the contact portion contains metal silicide.

4. The semiconductor device according to claim 3, wherein the metal silicide is titanium silicide, chromium silicide, zirconium silicide, molybdenum silicide, tungsten silicide, or hafnium silicide.

5. The semiconductor device according to claim 2, wherein the second portion of the contact portion contains a metal material.

6. The semiconductor device according to claim 5, wherein the metal material is titanium, chromium, zirconium, molybdenum, tungsten, or hafnium.

7. The semiconductor device according to claim 1, further comprising
an interlayer insulating film provided between the third semiconductor region and the second electrode,
wherein the first portion is aligned with the interlayer insulating film, and
the width of the second portion is larger than the width of the first portion at an upper end of the interlayer insulating film.

8. The semiconductor device according to claim 7, wherein the second portion of the contact portion contains metal silicide.

9. The semiconductor device according to claim 8, wherein the metal silicide is titanium silicide, chromium silicide, zirconium silicide, molybdenum silicide, tungsten silicide, or hafnium silicide.

10. The semiconductor device according to claim 7, wherein the second portion of the contact portion contains a metal material.

11. The semiconductor device according to claim 10, wherein the metal material is titanium, chromium, zirconium, molybdenum, tungsten, or hafnium.

12. The semiconductor device according to claim 1, wherein the second portion of the contact portion contains metal silicide.

13. The semiconductor device according to claim 12, wherein the metal silicide is titanium silicide, chromium silicide, zirconium silicide, molybdenum silicide, tungsten silicide, or hafnium silicide.

14. The semiconductor device according to claim 1, wherein the second portion of the contact portion contains a metal material.

15. The semiconductor device according to claim 14, wherein the metal material is titanium, chromium, zirconium, molybdenum, tungsten, or hafnium.

16. The semiconductor device according to claim 1, further comprising a fourth semiconductor region provided to surround the second portion and having an impurity concentration of a second conductive type higher than an impurity concentration of a second conductive type of the second semiconductor region.

17. The semiconductor device according to claim 1, wherein the first electrode is a drain electrode, the second electrode is a source electrode, the first semiconductor region is a drift region and a drain region, the second semiconductor region is a base region, and the third semiconductor region is a source region.

18. The semiconductor device according to claim 1, wherein the first conductive type is an n-type, and the second conductive type is a p-type.

19. A method for manufacturing a semiconductor device, comprising:
forming a trench for contact penetrating a source region of a first conductive type and reaching a base region of a second conductive type;
ion-implanting an impurity of a second conductive type into a bottom portion of the trench in an oblique direction with respect to a bottom surface of the trench to form an amorphous region extending in a lateral direction from the bottom portion of the trench;
depositing a metal thin film on a side surface and the bottom surface of the trench;
performing a heat treatment to form metal silicide in the amorphous region; and
depositing a metal material inside the trench.

20. A method for manufacturing a semiconductor device, comprising:
forming a trench for contact penetrating a source region of a first conductive type and reaching a base region of a second conductive type;
ion-implanting an impurity of a second conductive type into a bottom portion of the trench in an oblique direction with respect to a bottom surface of the trench to form an amorphous region extending in a lateral direction from the bottom portion of the trench;
performing a heat treatment in an oxygen atmosphere to form an oxide film in the amorphous region;
removing the oxide film to form a cavity portion;
depositing a metal thin film on a side surface of the trench and inside the cavity portion;
performing a heat treatment; and
depositing a metal material inside the trench.
